(19) United States
(12) Patent Application Publication
(10) Pub. No.: US 2016/0285034 A1
(43) Pub. Date: Sep. 29, 2016

(54) ORGANIC LIGHT-EMITTING DISPLAY APPARATUS

(71) Applicant: SAMSUNG DISPLAY CO., LTD., Yongin-si (KR)

(72) Inventors: Hyesog LEE, Osan-si (KR); Jaejoong KWON, Suwon-si (KR)

(21) Appl. No.: 14/857,847

(22) Filed: Sep. 18, 2015

(30) Foreign Application Priority Data
Mar. 26, 2015 (KR) 10-2015-0042383

(51) Int. Cl. H01L 51/52; H01L 51/50; H01L 27/32

(52) U.S. Cl. CPC H01L 51/5206; H01L 27/3244; H01L 51/5056; H01L 51/5072; H01L 51/5088; H01L 51/5092; H01L 51/5256; H01L 51/5221

(57) ABSTRACT

An organic light-emitting display apparatus, including a substrate having a pixel area; a first electrode on the substrate, the first electrode having a shape that is bent at least once; a second electrode spaced apart from the first electrode, the second electrode being on a same layer as the first electrode; and an organic layer on the substrate, the first electrode, and the second electrode, the organic layer covering the first electrode and the second electrode, a shortest distance by which the first electrode is spaced apart from the second electrode in a first direction that is parallel to the substrate being equal to a shortest distance by which the first electrode is spaced apart from the second electrode in a second direction that is parallel to the substrate and perpendicular to the first direction.

### CROSS-REFERENCE TO RELATED APPLICATION

Korean Patent Application No. 10-2015-0042383, filed on Mar. 26, 2015, in the Korean Intellectual Property Office, and entitled: “Organic Light-Emitting Display Apparatus,” is incorporated by reference herein in its entirety.

### BACKGROUND

1. Field

Embodiments relate to organic light-emitting display apparatuses.

2. Description of the Related Art

An organic light-emitting display apparatus may include an organic light-emitting device that may include an anode, an organic emission layer, and a cathode. The organic light-emitting device may emit light by energy that may be generated when excitons formed by the recombination of electrons and holes in the organic emission layer drop from an excited state to a ground state, and the organic light-emitting apparatus may display a predetermined image using the emission of light.

### SUMMARY

Embodiments may be realized by providing an organic light-emitting display apparatus, including a substrate having a pixel area; a first electrode on the substrate, the first electrode having a shape that is bent at least once; a second electrode spaced apart from the first electrode, the second electrode being on a same layer as the first electrode; and an organic layer on the substrate, the first electrode, and the second electrode, the organic layer covering the first electrode and the second electrode, a shortest distance by which the first electrode is spaced apart from the second electrode in a first direction that is parallel to the substrate being equal to a shortest distance by which the first electrode is spaced apart from the second electrode in a second direction that is parallel to the substrate and perpendicular to the first direction.

In a plan view, the first electrode may include a first portion extending in the first direction; and a first sub-portion extending in the second direction and connected to the first portion.

The first electrode may include more than one first sub-portion.

In plan view, the second electrode may include a second portion parallel to the first portion; and a second sub-portion connected to the second portion by extending in the second direction.

The first electrode may include more than one first sub-portion; the second electrode may include more than one second sub-portion; and the second sub-portions may be alternatingly disposed with the first sub-portions.

The second electrode may be alternatingly disposed with the first sub-portions by extending in the second direction.

The second electrode may face the first electrode and may have a shape that is bent at least once along the shape of the first electrode.

The first electrode and the second electrode may have a same shape.

The first electrode may be bent multiple times and may extend in one rotational direction, and the second electrode may be bent multiple times and may extend in the one rotational direction along the shape of the first electrode.

The organic light-emitting display apparatus may further include a hole transport region between the first electrode and the organic layer, the hole transport region covering the first electrode; and an electron transport region between the second electrode and the organic layer, the electron transport region covering the second electrode.

The hole transport region may include a hole injection layer covering the first electrode on the first electrode; and a hole transport layer covering the first electrode and the hole injection layer on the hole injection layer.

The electron transport region may include an electron injection layer covering the second electrode on the second electrode; and an electron transport layer covering the second electrode and the electron injection layer on the electron injection layer.

The organic light-emitting display apparatus may further include an encapsulation layer on the organic layer.

The organic light-emitting display apparatus may further include an insulation layer between the organic layer and the encapsulation layer.

A refractive index of the insulation layer may be smaller than a refractive index of the organic layer and may be equal to a refractive index of the encapsulation layer or greater than the refractive index of the encapsulation layer.

The insulation layer may include a plurality of insulation layers having different refractive indices, and a refractive index of each of the plurality of insulation layers may decrease in a direction toward the encapsulation layer.

### BRIEF DESCRIPTION OF THE DRAWINGS

Features will become apparent to those of skill in the art by describing in detail exemplary embodiments with reference to the attached drawings in which:

FIG. 1 illustrates a plan view schematically of an organic light-emitting display apparatus;

FIG. 2 illustrates a circuit diagram of a single pixel which is illustrated in FIG. 1;

FIG. 3 illustrates a plan view of a single pixel of an organic light-emitting display apparatus according to an embodiment;

FIG. 4 illustrates a cross-sectional view taken along line A-A′ of FIG. 3;

FIG. 5 illustrates a cross-sectional view of an enlarged portion of an organic light-emitting device layer of FIG. 4; and

FIGS. 6 through 9 illustrate plan views of single pixels of organic light-emitting display apparatuses according to embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

The meaning of “include,” “comprise,” “including,” or “comprising,” specifies a property, a region, a fixed number, a step, a process, an element and/or a component but does not exclude other properties, regions, fixed numbers, steps, processes, elements and/or components. Also, it will be understood that when an element such as a layer, film, region, or substrate is referred to as being “on” another element, it can be directly on the other element or intervening elements may also be present therebetween. In contrast, when an element such as a layer, film, region, or substrate is referred to as being “under” another element, it may be directly under the other element or intervening elements may also be present.

In the drawings, like reference numerals refer to like elements throughout. In the accompanying drawings, the dimensions of structures are exaggerated for clarity. It will be understood that although the terms first and second are used herein to describe various elements, these elements should not be limited by these terms. These terms are only used to distinguish one element from another element. For example, a first element could be termed a second element, and, similarly, a second element could be termed a first element. The terms of a singular form may include plural forms unless referred to the contrary.

Hereinafter, embodiments will be described with reference to the accompanying drawings.

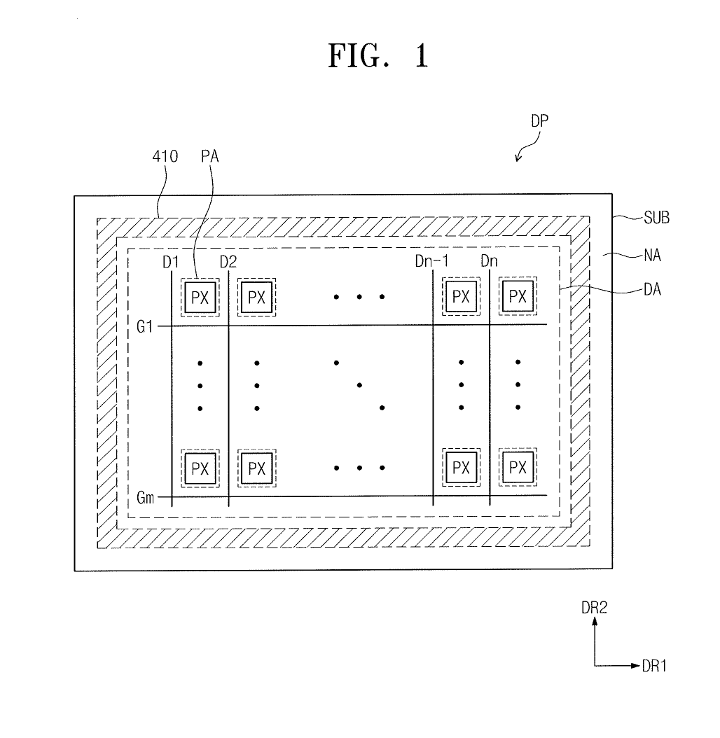

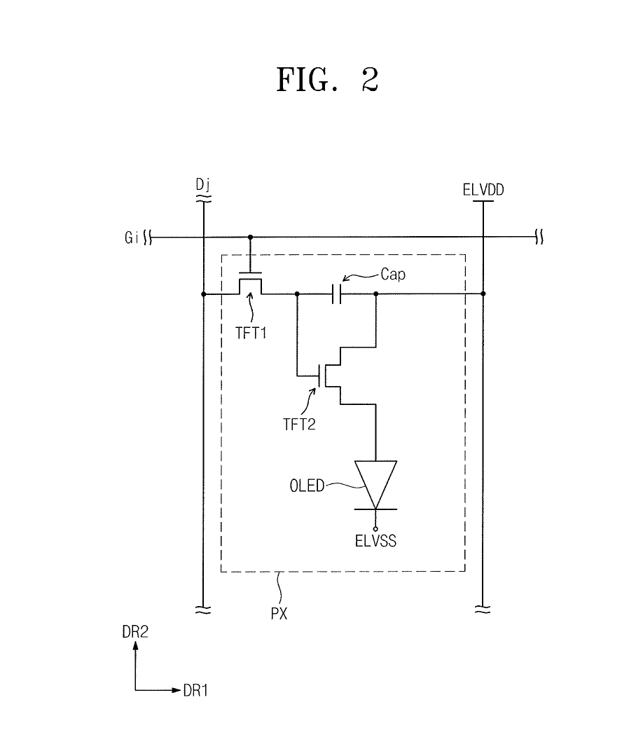

FIG. 1 illustrates a plan view schematically of an organic light-emitting display apparatus, and FIG. 2 illustrates a circuit diagram of a single pixel which is illustrated in FIG. 1.

Referring to FIG. 1, the organic light-emitting display apparatus may include an organic light-emitting display panel DP (hereinafter, referred to as “display panel”).

The display panel DP may include a display area DA displaying an image and a non-display area NA adjacent to the display area DA which may not display an image. The display area DA may include a plurality of pixel areas PA.

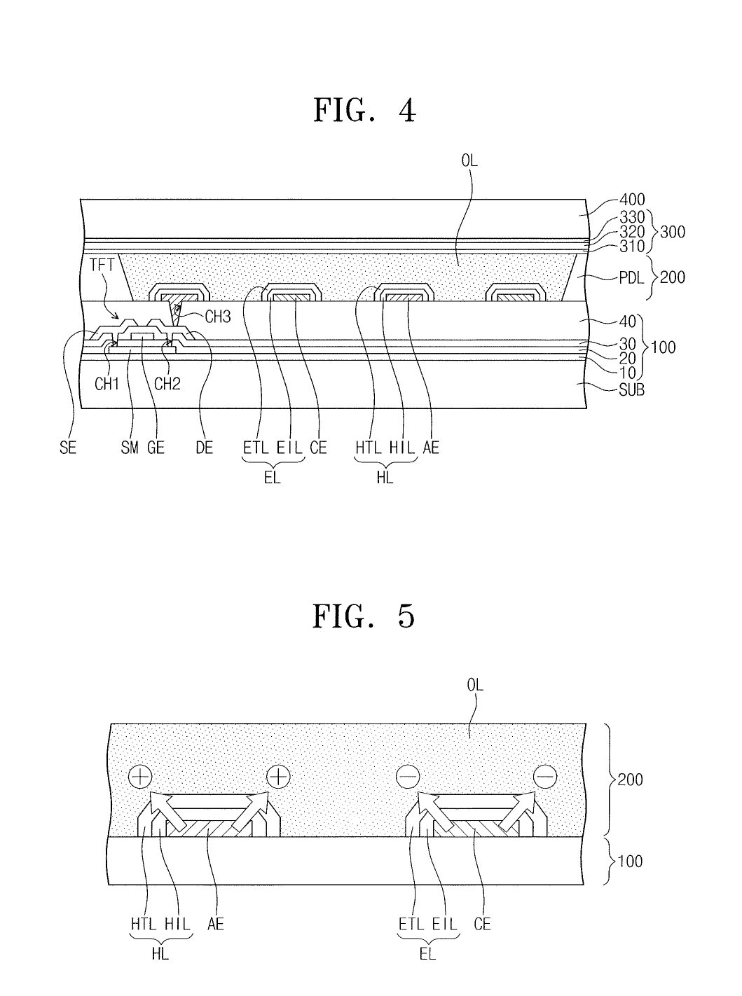

The display panel DP may include a substrate SUB (see FIG. 4), a plurality of gate lines G1 to Gm disposed on the substrate SUB, a plurality of data lines D1 to Dn, and a plurality of pixels PX.

The gate lines G1 to Gm and the data lines D1 to Dn may insulatively cross each other, e.g., the gate lines G1 to Gm and the data lines D1 to Dn may cross each other and be insulated from each other. In FIG. 1, it is exemplarily illustrated that the gate lines G1 to Gm extend in a first direction DR1 and the data lines D1 to Dn extend in a second direction DR2 which crosses the first direction DR1. In an embodiment, the gate lines G1 to Gm and the data lines D1 to Dn may insulatively cross each other, and the gate lines G1 to Gm and the data lines D1 to Dn may respectively have a partially curved shape instead of a linear shape. The gate lines G1 to Gm and the data lines D1 to Dn may define the pixel areas PA.

Each pixel PX may be included in each pixel area PA. Each pixel PX may be connected to any one of the gate lines G1 to Gm and any one of the data lines D1 to Dn to display an image. Each pixel PX may display red, green, or blue colors. In an embodiment, each pixel PX may display another color (e.g., white color) in addition to the red, green, and blue colors. In FIG. 1, it is exemplarily illustrated that each pixel PX may have a rectangular shape. In an embodiment, the shape of each pixel PX may be variously changed into a polygonal shape, a circular shape, or an elliptical shape.

FIG. 2 exemplarily illustrates a single pixel PX which may be connected to a single gate line Gi and a single data line Dj.

Referring to FIG. 2, the pixel PX may include a first transistor TFT1, a second transistor TFT2, a capacitor Cap, and an organic light-emitting diode (OLED).

The first transistor TFT1 may include a control electrode, which may be connected to the gate line Gi, an input electrode connected to the data line Dj, and an output electrode. The first transistor TFT1 may output a data signal, which may be applied to the data line Dj, by responding to a scanning signal which may be applied to the gate line Gi.

The capacitor Cap may include a first electrode, which may be connected to the first transistor TFT1, and a second electrode receiving a first power supply voltage ELVDD. The capacitor Cap may charge a quantity of electric charge corresponding to a difference between the first power supply voltage ELVDD and a voltage corresponding to the data signal which may be received from the first transistor TFT1.

The second transistor TFT2 may include a control electrode, which may be connected to the output electrode of the first transistor TFT1 and the first electrode of the capacitor Cap, an input electrode receiving the first power supply voltage ELVDD, and an output electrode. The output electrode of the second transistor TFT2 may be connected to the organic light-emitting diode OLED.

The second transistor TFT2 may control a driving current which may flow through the organic light-emitting diode OLED corresponding to the quantity of electric charge stored in the capacitor Cap. Turn-on time of the second transistor TFT2 may be determined according to the quantity of electric charge charged in the capacitor Cap. The output electrode of the second transistor TFT2 may substantially provide a voltage lower than the first power supply voltage ELVDD to the organic light-emitting diode OLED.

The display panel DP may further include a driving voltage line. The driving voltage line may extend parallel to the gate line Gi or may extend parallel to the data line Dj. The driving voltage line may receive the first power supply voltage ELVDD and may be connected to the input electrode of the second transistor TFT2.

The organic light-emitting diode OLED may include a first electrode, which may be connected to the second transistor TFT2, and a second electrode receiving the second power supply voltage ELVSS. The organic light-emitting diode OLED may emit light during a turn-on period of the second transistor TFT2. A color of the light generated from the organic light-emitting diode OLED may be determined by a material constituting the organic light-emitting pattern. For example, the color of the light generated in the organic light-emitting diode OLED may be red, green, blue, or white.

The display panel DP may further include a sealing member 410. The sealing member 410 may be disposed to surround the display area DA and may prevent the organic light-emitting diode OLED from being exposed to external moisture and air.

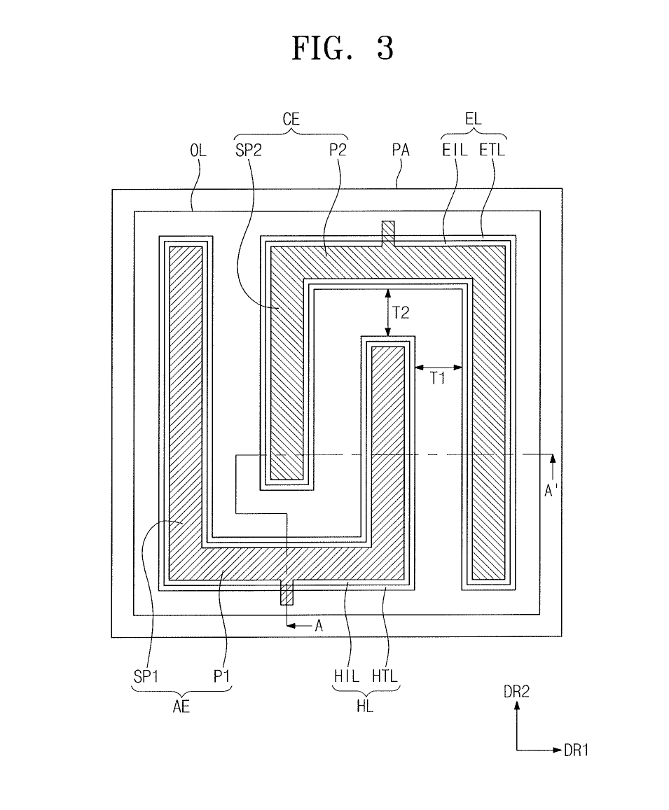

FIG. 3 illustrates a plan view of a single pixel of an organic light-emitting display apparatus according to an embodiment, and FIG. 4 illustrates a cross-sectional view taken along line A-A′ of FIG. 3.

Referring to FIGS. 3 and 4, the organic light-emitting display apparatus may include a substrate SUB, a driving element layer 100, an organic light-emitting element layer 200, and an encapsulation layer 400.

In an embodiment, the substrate SUB may be a flexible substrate, and may be formed of a plastic having excellent heat resistance and durability, such as polyethylene terephthalate, polyethylene naphthalate, polycarbonate, polyarylate, polyetherimide, polyethersulfone, and polyimide. In an embodiment, the substrate SUB may be formed of various materials such as metal or glass.

The driving element layer 100 may be formed on the substrate SUB. A barrier layer 10 formed on the substrate SUB may be included in the driving element layer 100.

The barrier layer 10 may prevent external foreign matter, such as moisture or oxygen, on the substrate SUB from penetrating the organic light-emitting element layer 200 through the substrate.

Thin film transistors formed on the barrier layer 10 may be included in the driving element layer 100. The thin film transistors may be the first transistor TFT1 (see FIG. 2) and the second transistor TFT2 (see FIG. 2). Hereinafter, it will be illustrated that a single thin film transistor TFT may be formed in the driving element layer 100.

The thin film transistor TFT may include an active layer SM, a gate electrode GE, a source electrode SE, and a drain electrode DE.

The active layer SM may be disposed on the barrier layer 10. The driving element layer 100 may further include a first insulation layer 20 which may be disposed between the active layer SM and the gate electrode GE. The first insulation layer 20 may insulate the active layer SM and the gate electrode GE from each other. The source electrode SE and the drain electrode DE may be disposed on the gate electrode GE.

The driving element layer 100 may further include a second insulation layer 30 which may be disposed between the gate electrode GE and the source electrode SE and between the gate electrode GE and the drain electrode DE. The source electrode SE may be connected to the active layer SM through a first contact hole CH1 which may be included in the first insulation layer 20 and the second insulation layer 30, and the drain electrode DE may be connected to the active layer SM through a second contact hole CH2 which may be included in the first insulation layer 20 and the second insulation layer 30.

Embodiments are not limited to the structure of the transistor TFT illustrated in FIG. 4, and positions of the active layer SM, the gate electrode GE, the source electrode SE, and the drain electrode DE may be variously changed. For example, it is illustrated in FIG. 4 that the gate electrode GE may be disposed on the active layer SM. In an embodiment, the gate electrode GE may be disposed under the active layer SM.

The driving element layer 100 may further include a protective layer 40 which may be disposed on the source electrode SE and the drain electrode DE.

The organic light-emitting element layer 200 may be disposed on the protective layer 40. The organic light-emitting element layer 200 may include a first electrode AE, a second electrode CE, a hole transport region HL, an electron transport region EL, and an organic layer OL.

The first electrode AE may be disposed on the protective layer 40. The first electrode AE may be a pixel electrode or an anode. The first electrode AE may generate holes by being connected to the drain electrode DE through a third contact hole CH3 which may be formed in the protective layer 40.

The first electrode AE may be a transmissive electrode, a transflective electrode, or a reflective electrode. In the case that the first electrode AE is a transmissive electrode, the first electrode AE may be formed of a transparent metal oxide, for example, indium tin oxide (ITO), indium zinc oxide (IZO), zinc oxide (ZnO), and indium tin zinc oxide (ITZO). In the case in which the first electrode AE is a transflective electrode or a reflective electrode, the first electrode AE may include silver (Ag), magnesium (Mg), aluminum (Al), platinum (Pt), palladium (Pd), gold (Au), nickel (Ni), neodymium (Nd), iridium (Ir), chromium (Cr), or a mixture of metals.

The first electrode AE may have a single-layer structure formed of a transparent metal oxide or metal, or a multilayered structure having a plurality of layers. For example, the first electrode AE may have a single-layer structure of ITO, Ag, or a metal mixture (e.g., mixture of Ag and Mg), a double-layer structure of ITO/Mg or ITO/MgF, or a triple-layer structure of ITO/Ag/ITO.

In a plan view, the first electrode AE according to an embodiment may have a shape that may be bent at least once.

The second electrode CE may be formed on the protective layer 40. The second electrode CE may be disposed by being spaced apart from the first electrode AE at a predetermined interval. The second electrode CE may be a common electrode or a cathode. The second electrode CE may receive the second power supply voltage ELVSS and may generate electrons.

The second electrode CE may be a transmissive electrode, a transflective electrode, or a reflective electrode. In the case that the second electrode CE is a transmissive electrode, the second electrode CE may include lithium (Li), calcium (Ca), LiF/Ca, LiF/Al, Al, Mg, BaF, barium (Ba), Ag, or a compound or mixture thereof (e.g., mixture of Ag and Mg). The second electrode CE may include an auxiliary electrode. The auxiliary electrode may include a layer, which may be formed by depositing the above material to face the organic layer OL, and a transparent metal oxide on the layer, for example, indium tin oxide (ITO), indium zinc oxide (IZO), zinc oxide (ZnO), indium tin zinc oxide (ITZO), molybdenum (Mo), and titanium (Ti).

In the case in which the second electrode CE is a transflective electrode or a reflective electrode, the second electrode CE may include Ag, Mg, Al, Pt, Pd, Au, Ni, Nd, Ir, Cr, Li, Ca, LiF/Ca, LiF/Al, Mo, Ti, or a compound or mixture thereof (e.g., mixture of Ag and Mg). The second electrode CE may have a multilayered structure including a reflective layer or transflective layer, which may be formed of the above material, and a transparent conductive layer which may be formed of ITO, IZO, ZnO, or ITZO.

The second electrode CE according to an embodiment may be formed by being spaced apart from the first electrode AE at a predetermined interval.

Referring to FIG. 3, at least a portion of the first electrode AE may be disposed parallel to at least a portion of the second electrode CE. A first distance T1, the shortest distance by which the first electrode AE is spaced apart from the second electrode CE in the first direction DR1, may be substantially the same as a second distance T2, the shortest distance by which the first electrode AE is spaced apart from the second electrode CE in the second direction DR2.

The first electrode AE may include a first portion P1 extending in the first direction DR1, and a first sub-portion SP1 extending in the second direction DR2 and connected to the first portion P1. In an embodiment, it is illustrated that the number of the first sub-portions SP1 is two. In an embodiment, the one or the plurality of first sub-portions SP1 may be provided.

In the case that the plurality of first sub-portions SP1 is provided, the first sub-portions may be disposed by being spaced apart from each other at a predetermined interval. The first sub-portions SP1 may be provided in different lengths.

The second electrode CE may include a second portion P2 parallel to the first portion P1 and a second sub-portion SP2 connected to the second portion P2. The second sub-portion SP2 may extend in the second direction DR2, and may be alternatingly disposed with the first sub-portion SP1.

In an embodiment, it is illustrated that the number of the second sub-portions SP2 is two. In an embodiment, the one or three or more second sub-portions SP2 may be provided. In the case that the plurality of second sub-portions SP2 is provided, the plurality of second sub-portions SP2 may be provided in different lengths.

It is illustrated that a thickness of the first electrode AE and a thickness of the second electrode CE are the same. In an embodiment, the thickness of the first electrode AE and the thickness of the second electrode CE may be formed to be different. A thickness of a portion of the first electrode AE may be formed to be different or a thickness of a portion of the second electrode CE may be formed to be different.

The hole transport region HL may be disposed on the first electrode AE to cover the first electrode AE. In a plan view, the hole transport region HL may be disposed to correspond to the shape of the first electrode AE.

The hole transport region HL may include a hole injection layer HIL and a hole transport layer HTL. The hole injection layer HIL may be disposed on the first electrode AE to cover the first electrode AE. The hole transport layer HTL may be disposed on the hole injection layer HIL to cover the first electrode AE and the hole injection layer HIL.

The structure of the hole transport region HL is not limited thereto, and the hole transport region HL may have a single-layer structure formed of a single material, a single-layer structure formed of a plurality of different materials, or a multilayered structure having a plurality of layers which may be formed of a plurality of different materials. For example, the hole transport region HL may have a single-layer structure formed of a plurality of different materials or may have a structure of hole injection layer/hole transport layer, hole injection layer/hole transport layer/buffer layer, hole injection layer/buffer layer, hole transport layer/buffer layer, or hole injection layer/hole transport layer/electron blocking layer, which are sequentially stacked from the first electrode AE.

The hole transport region HL may be formed by using various methods such as a vacuum deposition method, a spin coating method, a casting method, a Langmuir-Blodgett (LB) method, an inkjet printing method, a laser printing method, and a Laser Induced Thermal Imaging (LITI) method.

In the case that the hole transport region HL includes the hole injection layer HIL, the hole transport region HL may include, for example, a phthalocyanine compound such as copper phthalocyanine; N,N′-diphenyl-N,N′-bis-[4-(phenyl-m-tolyl-amino)-phenyl]-biphenyl-4,4′diamine (DNTPD), 4,4′,4″-tris(3-methylphenyl phenylamino)triphenylamine (m-MTDATA), 4,4′4″-tris(N,N-diphenylamino)triphenylamine (TDATA), 4,4′,4″-tris{N,-(2-naphthyl)-N-phenylamino}-triphenylamine (2TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), or (polyaniline)/poly(4-styrenesulfonate) (PANI/PSS).

In the case that the hole transport region HL includes the hole transport layer HTL, the hole transport region HL may include, for example, a carbazole-based derivative such as N-phenyl carbazole and polyvinyl carbazole, a fluorine-based derivative, a triphenylamine-based derivative such as N,N-bis(3-methylphenyl)-N,N-diphenyl-[1,1-biphenyl]-4,4′diamine (TPD) and 4,4′,4″-tris(N-carbazolyl)triphenylamine (TCTA), N,N′-di(1-naphthyl)-N,N-diphenylbenzidine (NPB), or 4,4′-cyclohexylidene bis[N,N-bis(4-methylphenyl)benzenamine] (TAPC).

A thickness of the hole transport region HL may be in a range of about 100 Å to about 10,000 Å, for example, about 100 Å to about 1,000 Å. When the hole transport region HL includes both the hole injection layer HIL and the hole transport layer HTL, a thickness of the hole injection layer HIL may be in a range of about 100 Å to about 10,000 Å, for example, about 100 Å to about 1,000 Å, and a thickness of the hole transport layer HTL may be in a range of about 50 Å to about 2,000 Å, for example, about 100 Å to about 1,500 Å. In the case that the thicknesses of the hole transport region HL, the hole injection layer HIL, and the hole transport layer HTL respectively satisfy the above-described ranges, satisfactory hole transport characteristics may be obtained without a substantial increase in driving voltage.

The hole transport region HL may further include a charge generating material for improving conductivity in addition the above-described materials. The charge generating material may be uniformly or non-uniformly dispersed in the hole transport region HL. The charge generating material, for example, may be a p-dopant. The p-dopant may be, for example, one of a quinone derivative, a metal oxide, and a cyano group-containing compound. For example, examples of the p-dopant may include a quinone derivative such as tetracyanoquinodimethane (TCNQ) and 2,3,5,6-tetrafluoro-tetracyanoquinodimethane (F4-TCNQ); and a metal oxide such as tungsten oxide and molybdenum oxide.

As described above, the hole transport region HL may further include at least one of a buffer layer and an electron blocking layer in addition to the hole injection layer HIL and the hole transport layer HTL. The buffer layer may increase luminous efficiency by compensating a resonance distance according to a wavelength of the light emitted from the organic layer OL. The material, which may be included in the hole transport region HL, may be used as a material included in the buffer layer. The electron blocking layer may be a layer which may prevent the injection of electrons from the electron transport region EL to the hole transport region HL.

The electron transport region EL may be disposed on the second electrode CE to cover the second electrode CE. In a plan view, the electron transport region EL may be disposed to correspond to the shape of the second electrode CE.

The electron transport region EL may include an electron injection layer EIL and an electron transport layer ETL. The electron injection layer EIL may be disposed on the second electrode CE to cover the second electrode CE. The electron transport layer ETL may be disposed on the electron injection layer EIL to cover the second electrode CE and the electron injection layer EIL.

The structure of the electron transport region EL is not limited thereto, and, for example, the electron transport region EL may have a structure of electron transport layer/electron injection layer or hole blocking layer/electron transport layer/electron injection layer which are sequentially stacked from the second electrode CE, or may have a single-layer structure in which two or more layers are mixed.

The electron transport region EL may be formed by using various methods such as a vacuum deposition method, a spin coating method, a casting method, a Langmuir-Blodgett (LB) method, an inkjet printing method, a laser printing method, and a Laser Induced Thermal Imaging (LITI) method.

In the case that the electron transport region EL includes the electron transport layer ETL, the electron transport region EL may include, for example, tris(8-hydroxyquinolinato)aluminum (Alq3), 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-l-yl)-3,5-diphenyl-4H-1,2,4-triazole (NTAZ), 2-(4-biphenylyl)-5-(4-tertbutylphenyl)-1,3,4-oxadiazole (tBu-PBD), bis(2-methyl-8-quinolinolato-N1,O8)-(1,1′biphenyl-4-olato)aluminum (BAlq), berylliumbis(benzoquinolin-10-olate) (Bebq2), 9,10-di(naphthalene-2-yl)anthracene (ADN), and a mixture thereof. A thickness of the electron transport region EL may be in a range of about 100 Å to about 1,000 Å, for example, about 150 Å to about 500 Å. In the case that the thickness of the electron transport layer ETL satisfies the above-described range, satisfactory electron transport characteristics may be obtained without a substantial increase in driving voltage.

In the case that the electron transport region EL includes the electron injection layer EIL, for example, a lanthanide metal, such as LiF, lithium quinolate (LiQ), Li₂O, BaO, NaCl, CsF, and ytterbium (Yb), or a metal halide, such as RbCl and RbI, may be used as the electron transport region HL. The electron injection layer EIL may also be formed of a material in which an electron transport material and an insulating organic metal salt are mixed. The organic metal salt may be a material having an energy bandgap of about 4 eV. For example, the organic metal salt may include metal acetate, metal benzoate, metal acetoacetate, metal acetylacetonate, or metal stearate. A thickness of the electron injection layer EIL may be in a range of about 1 Å to about 100 Å, for example, about 3 Å to about 90 Å. In the case that the thickness of the electron injection layer EIL satisfies the above-described range, satisfactory electron injection characteristics may be obtained without a substantial increase in driving voltage.

As described above, the electron transport region EL may further include the hole blocking layer. The hole blocking layer, for example, may include one or more of 2,9-dimethyl-4,7-diphenyl-1,10-phenanthroline (BCP) or 4,7-diphenyl-1,10-phenanthroline (Bphen). A thickness of the hole blocking layer may be in a range of about 20 Å to about 1,000 Å, for example, about 30 Å to about 300 Å. In the case that the thickness of the hole blocking layer satisfies the above-described range, hole blocking characteristics may be improved without a substantial increase in driving voltage.

The organic light-emitting element layer 200 may further include a pixel-defining layer PDL which may be disposed on the protective layer 40. The pixel-defining layer PDL may be planarly superposed, e.g., may be planar and may be uperposed, on an interface of the pixel areas PA.

The organic layer OL may be formed on the hole transport region HL, the electron transport region EL, and the protective layer 40.

The organic layer OL may have a single-layer structure formed of a single material, a single-layer structure formed of a plurality of different materials, or a multilayered structure having a plurality of layers which may be formed of a plurality of different materials

The organic layer OL may be formed by using various methods such as a vacuum deposition method, a spin coating method, a casting method, a Langmuir-Blodgett (LB) method, an inkjet printing method, a laser printing method, and a Laser Induced Thermal Imaging (LITI) method.

An exemplary material of the organic layer OL is one that may be used in the art. For example, the organic layer OL may be formed of materials emitting red, green, and blue, and may include a fluorescence material or a phosphorescence material. The organic layer OL may include a host and a dopant.

An exemplary material of the host is one that may be used in the art, and, for example, tris(8-hydroxyquinolino)aluminum (Alq3), 4,4′bis(N-carbazolyl)-1,1′biphenyl (CBP), poly(n-vinylcabazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′bis(9-carbazolyl)-2,2′dimethyl-biphenyl (CDBP), and 2-methyl-9,10-bis(naphthalen-2-yl)anthracene (MADN) may be used.

When the organic layer OL emits red light, the organic layer OL, for example, may include a fluorescence material including PBD:Eu(DBM)3(Phen) (tris(dibenzoylmethanato)phenanthoroline europium) or perylene. When the organic layer OL emits red light, the dopant included in the organic layer OL, for example, may be selected from metal complexes or organometallic complexes, such as bis(1-phenylisoquinoline)acetylacetonate iridium (PIQIr(acac)), bis(1-phenylquinoline)acetylacetonate iridium (PQIr(acac)), tris(1-phenylquinoline)iridium (PQIr), and octaethylporphyrin platinum (PtOEP).

When the organic layer OL emits green light, the organic layer OL, for example, may include a fluorescence material including tris(8-hydroxyquinolino)aluminum (Alq3). When the organic layer OL emits green light, the dopant included in the organic layer OL, for example, may be selected from metal complexes or organometallic complexes, such as fac-tris(2-phenylpyridine)iridium (Ir(ppy)3).

When the organic layer OL emits blue light, the organic layer OL, for example, may include a fluorescence material which may include one of spiro-DPVBi, spiro-6P, distyryl-benzene (DSB), distyryl-arylene (DSA), a polyfluorene (PFO)-based polymer, and a poly(p-phenylene vinylene) (PPV)-based polymer. When the organic layer OL emits blue light, the dopant included in the organic layer OL, for example, may be selected from metal complexes or organometallic complexes, such as (4,6-F2ppy)2Irpic.

The encapsulation layer 400 may be disposed on the organic layer OL and the pixel-defining layer PDL to cover the display area DA (see FIG. 1). The encapsulation layer 400 may be formed of an organic layer or an inorganic layer. In an embodiment, the encapsulation layer 400 may be provided as a substrate that may be formed of glass or plastic.

The organic light-emitting display apparatus may further include an insulation layer 300 which may be disposed between the encapsulation layer 400 and the organic layer OL.

The insulation layer 300 may be formed of a plurality of layers which may be formed of an insulation material. The insulation layer 300 may have a refractive index which is smaller than a refractive index of the organic layer OL and is greater than a refractive index of the encapsulation layer 400. The refractive index of the insulation layer 300 may be the same as the refractive index of the encapsulation layer 400.

In an embodiment, the insulation layer 300 may include first to third layers 310, 320, and 330. At least one of the first to third layers 310, 320, and 330 may be formed of different materials from adjacent different layers.

The first to third layer 310, 320, and 330 may have different refractive indices. The refractive index of the third layer 330 is smaller than the refractive index of the second layer 320 and the refractive index of the first layer 310. The refractive index of the second layer 320 may be smaller than the refractive index of the first layer 310 or may be the same as the refractive index of the first layer 310.

In the embodiment, it is illustrated that the insulation layer 300 may be composed of the first to third layers 310, 320, and 330. In an embodiment, the insulation layer 300 may be composed of a single layer or a plurality of layers if the insulation layer 300 may fill a space between the organic layer OL and the encapsulation layer 400 to some extent.

In the case that an air layer is formed between the organic layer OL and the encapsulation layer 400, light emitted from the organic layer OL may be again incident onto the organic layer OL by being refracted by the air layer. The thickness of the air layer may be minimized by disposing the insulation layer 300 between the organic layer OL and the encapsulation layer 400. The light emitted from the organic layer OL may be emitted to the outside of the organic light-emitting display apparatus through the insulation layer 300 and the encapsulation layer 400.

FIG. 5 illustrates a cross-sectional view of an enlarged portion of an organic light-emitting device layer of FIG. 4.

Referring to FIGS. 3 to 5, holes (+) and electrons (−) respectively from the first electrode AE and the second electrode CE may be injected into the organic layer OL. Excitons, in which the holes (+) and electrons (−) are combined, may be formed in the organic layer OL, for example, a region between the first electrode AE and the second electrode CE and a region perpendicular to the region between the first electrode AE and the second electrode CE, and light may be emitted when the excitons drop from an excited state to a ground state.

In the organic layer OL, some light may be emitted from the first electrode AE and the second electrode CE. A region from which the light may be emitted in the organic layer OL may be not only the region between the first electrode AE and the second electrode CE but may also be at least a portion of the top of the first electrode AE, which may be adjacent to the region between the first electrode AE and the second electrode CE, and at least a portion of the top of the second electrode CE which may be adjacent to the region between the first electrode AE and the second electrode CE.

Hereinafter, organic light-emitting display apparatuses according to embodiments will be described with reference to the accompanying drawings. In embodiments, shapes of the first electrode AE and the second electrode CE may be variously provided. For the simplicity of the description, descriptions overlapping with the above embodiment will be omitted.

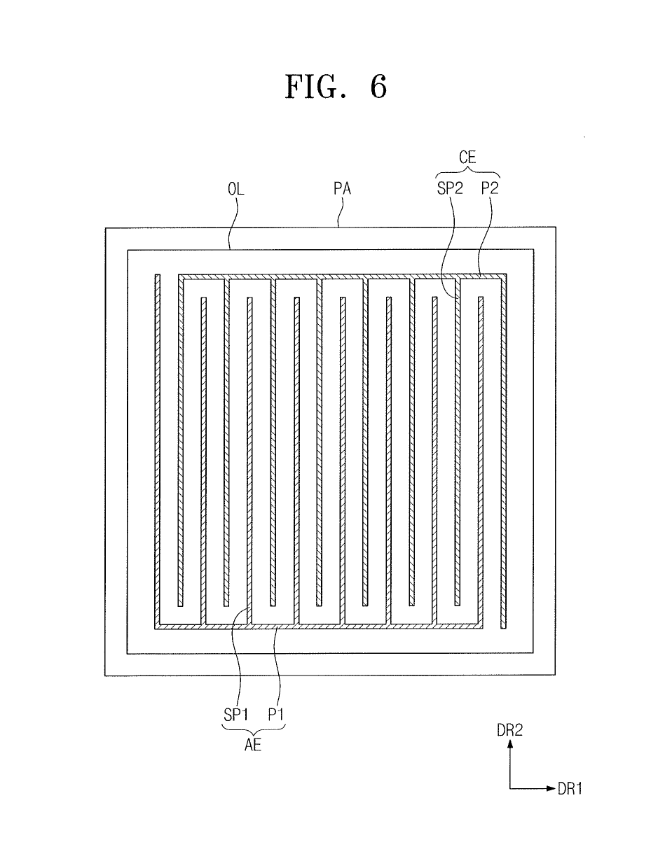

FIGS. 6 through 9 illustrate plan views of single pixels of the organic light-emitting display apparatuses according to embodiments.

First, referring to FIG. 6, the first electrode AE may include a first portion P1 extending in the first direction DR1, and a plurality of first sub-portions SP1 extending in the second direction DR2 and connected to the first portion P1. Each of the first sub-portions SP1 may be disposed by being spaced apart at a predetermined interval.

In the embodiment, it is illustrated that the eight first sub-portions SP1 may be provided, but the number of the first sub-portions SP1 is not limited thereto.

The second electrode CE may include a second portion P2 parallel to the first portion P1 and a plurality of second sub-portions SP2 parallel to the first sub-portions SP1 and connected to the second portion P2. Each of the second sub-portions SP2 may be spaced apart at a predetermined interval and may be alternatingly disposed with the first sub-portions SP1.

In the embodiment, it is illustrated that the eight second sub-portions SP2 may be provided, but the number of the second sub-portions SP2 is not limited thereto. In the case that the first sub-portions SP1 and the second sub-portions SP2 are alternatingly disposed, the number of the first sub-portions SP1 and the number of the second sub-portions SP2 may be different from each other.

Each of the first sub-portions SP1 may be disposed by being spaced apart from the second sub-portions SP2 adjacent to each other at a predetermined interval in the first direction DR1.

One end of the second sub-portion SP2, which is opposite to the other end of the second sub-portion SP2 connected to the second portion P2, may face the first portion P1. One end of the first sub-portion SP1, which is opposite to the other end of the first sub-portion SP1 connected to the first portion P1, may face the second portion P2.

A distance from one first sub-portion SP1 to one second sub-portion SP2 adjacent to the one first sub-portion SP1 may be the same as a distance from one end of the one first sub-portion SP1 to the second portion P2. The distance from one first sub-portion SP1 to one second sub-portion SP2 adjacent to the one first sub-portion SP1 may be the same as a distance from one end of the second sub-portion SP2 to the first portion P1.

Since the plurality of first sub-portions SP1 and the plurality of second sub-portions SP2 may be provided, a plurality of areas between the first sub-portions SP1 and the second sub-portions SP2 may be provided. A plurality of areas from which light may be emitted between the first electrode AE and the second electrode CE may be formed, and the luminous efficiency of the organic light-emitting display apparatus may be improved.

The smaller the distance from the first sub-portions SP1 to the second sub-portions SP2 is, the more densely the light-emitting areas between the first electrode AE and the second electrode CE may be formed. Thus, dark spots of the organic light-emitting display apparatus may be reduced.

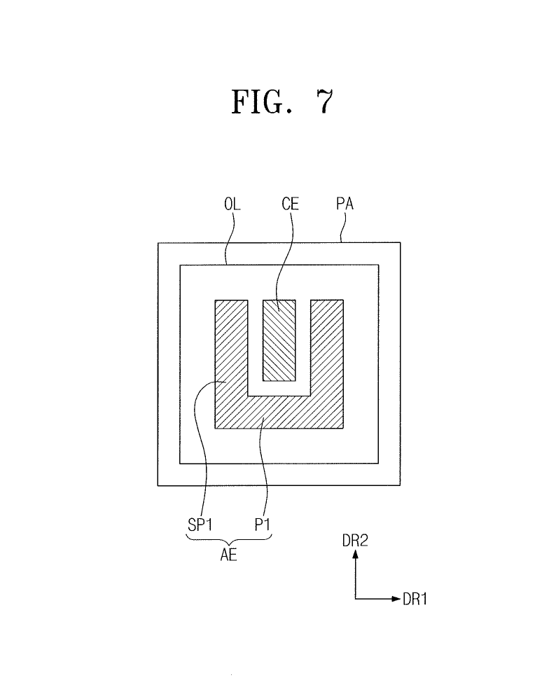

Referring to FIG. 7, the first electrode AE and the second electrode CE may be provided in different shapes. In an embodiment, the first electrode AE, as in the embodiment, may include a first portion P1 extending in the first direction DR1 and two first sub-portions SP1 connected to the first portion P1 and extending in the second direction DR2.

In contrast, the second electrode CE may be parallel to the first sub-portions SP1 and may extend in the second direction DR2. The second electrode CE may be disposed between the first sub-portions SP1 which are disposed by being spaced apart from each other at a predetermined interval. The first electrode AE may be provided in a bent shape, but the second electrode CE may be provided in a bar shape.

The shortest distance from the first portion P1 to the second electrode CE may be the same as the shortest distance from the first sub-portion SP1 to the second electrode CE.

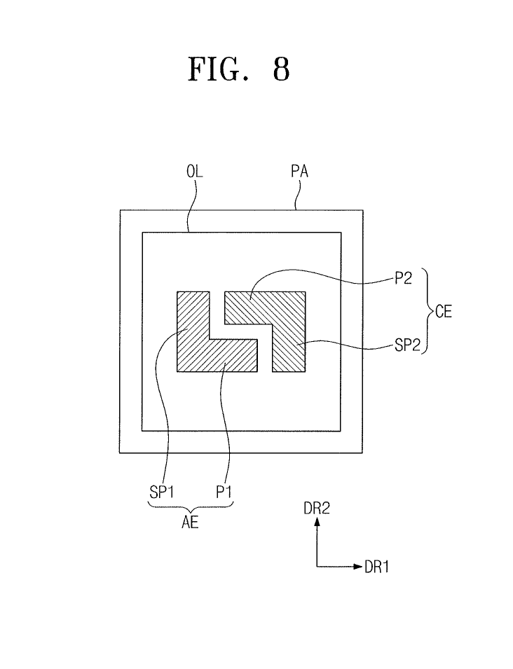

Referring to FIG. 8, the first electrode AE and the second electrode CE may each have a shape that is bent once. Herein, the first electrode AE and the second electrode CE may be origin-symmetrically disposed.

The first electrode AE may include a first portion P1 extending in the first direction DR1 and a first sub-portion SP1 bent and extending from the first portion P1.

The second electrode CE may include a second portion P2, which may extend in the first direction DR1 to face the first portion P1, and a second sub-portion SP2 which may be bent and may extend from the second portion P2 to face the first sub-portion SP1.

The shortest distance from the first portion P1 to the second portion P2 may be the same as the shortest distance from the first portion P1 to the second sub-portion SP2. The shortest distance from the first portion P1 to the second portion P2 may be the same as the shortest distance from the second portion P2 to the first sub-portion SP1.

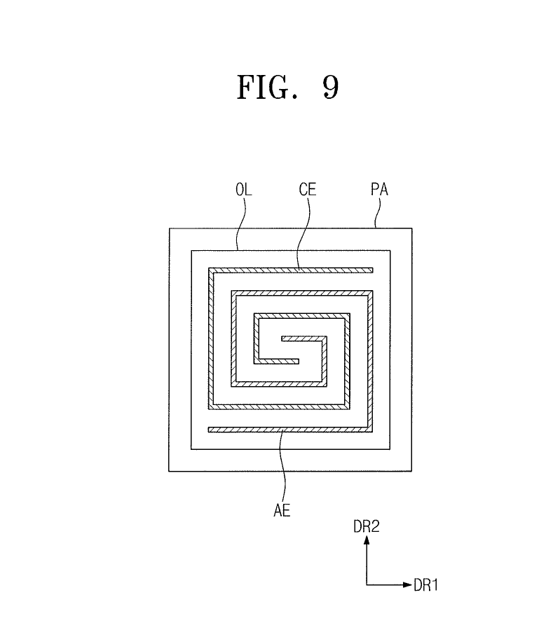

Referring to FIG. 9, the first electrode AE may be bent multiple times and extend in a clockwise direction on the basis of one end of the first electrode AE which may be located at the center of a pixel area PA, e.g., the first electrode AE may have one end disposed therebetween. Whenever the first electrode AE is bent and extends, the first electrode AE may extend to a length that is longer than an extended length before the bent. Herein, it is illustrated that the first electrode AE may be bent about 90 degrees, but the bent angle is not particularly limited. The first electrode AE may be bent and extend to form a curved surface.

The second electrode CE may be bent multiple times and extend in the clockwise direction on the basis of one end of the second electrode CE which may face the one end of the first electrode AE. The second electrode CE may extend parallel to the first electrode AE along the shape of the first electrode AE.

It is illustrated that the first electrode AE and the second electrode CE may be bent and extend in the clockwise direction. In an embodiment, the first electrode AE and the second electrode CE may be bent and extend in an anticlockwise direction.

A plurality of dense areas between the first electrode AE and the second electrode CE may be formed as the first electrode AE and the second electrode CE may be bent and extend in one rotational direction. Accordingly, the luminous efficiency may be improved by reducing the dark spots of the organic light-emitting display apparatus.

The first electrode AE and the second electrode CE may be variously provided in the same shape or different shapes. In embodiments, it is illustrated that the first electrode AE may be bent at least once. The second electrode CE may have a shape that may be bent at least once, and the shape of the first electrode AE may not be limited. One or more of the first electrode AE or the second electrode CE may have a bent shape.

By way of summation and review, an organic light-emitting display apparatus may have self-luminance characteristics, and since the organic light-emitting display apparatus, different from a liquid crystal display, may not require a separate light source, the thickness and weight thereof may be reduced. Since the organic light-emitting display apparatus may have high-quality characteristics, such as low power consumption, high brightness, and high-speed response, the organic light-emitting display apparatus may be an appropriate advanced display.

With respect to the organic light-emitting display apparatus, a ratio of light emitted to the outside of the organic light-emitting display apparatus to light, which is emitted obliquely to a substrate among the light emitted from the organic emission layer, may not be high.

Provided is an organic light-emitting display apparatus that may have improved light extraction efficiency. Also provided is an organic light-emitting display apparatus that may have a relatively wide light-emitting area.

An organic light-emitting display apparatus according to an embodiment may improve luminous efficiency.

In embodiments, the first electrode and the second electrode may be provided in various shapes. In an embodiment, the first electrode and the second electrode may be provided in different shapes. The second electrode may be provided in a bar shape that may extend in the second direction. The second electrode may be alternatingly disposed with the first sub-portions between the first sub-portions of the first electrode.

The second electrode may face the first electrode and may have a shape that may be bent at least once along the shape of the first electrode. In the case that the first electrode and the second electrode are provided in the same shape, the first electrode and the second electrode may be origin-symmetrically disposed.

The first electrode having one end of the first electrode disposed therebetween may be bent multiple times and may extend in one rotational direction, and the second electrode may be bent multiple times and may extend in the one rotational direction along the shape of the first electrode.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting display apparatus, comprising:
a substrate having a pixel area;
a first electrode on the substrate, the first electrode having a shape that is bent at least once;
a second electrode spaced apart from the first electrode, the second electrode being on a same layer as the first electrode; and
an organic layer on the substrate, the first electrode, and the second electrode, the organic layer covering the first electrode and the second electrode,
a shortest distance by which the first electrode is spaced apart from the second electrode in a first direction that is parallel to the substrate being equal to a shortest distance by which the first electrode is spaced apart from the second electrode in a second direction that is parallel to the substrate and perpendicular to the first direction.

2. The organic light-emitting display apparatus as claimed in claim 1, wherein, in a plan view, the first electrode includes:
a first portion extending in the first direction; and
a first sub-portion extending in the second direction and connected to the first portion.

3. The organic light-emitting display apparatus as claimed in claim 2, wherein the first electrode includes more than one first sub-portion.

4. The organic light-emitting display apparatus as claimed in claim 2, wherein, in plan view, the second electrode includes:
a second portion parallel to the first portion; and
a second sub-portion connected to the second portion by extending in the second direction.

5. The organic light-emitting display apparatus as claimed in claim 4, wherein:
the first electrode includes more than one first sub-portion;
the second electrode includes more than one second sub-portion; and
the second sub-portions are alternatingly disposed with the first sub-portions.

6. The organic light-emitting display apparatus as claimed in claim 3, wherein the second electrode is alternatingly disposed with the first sub-portions by extending in the second direction.

7. The organic light-emitting display apparatus as claimed in claim 1, wherein the second electrode faces the first electrode and has a shape that is bent at least once along the shape of the first electrode.

8. The organic light-emitting display apparatus as claimed in claim 7, wherein the first electrode and the second electrode have a same shape.

9. The organic light-emitting display apparatus as claimed in claim 7, wherein:
the first electrode is bent multiple times and extends in one rotational direction, and
the second electrode is bent multiple times and extends in the one rotational direction along the shape of the first electrode.

10. The organic light-emitting display apparatus as claimed in claim 1, further comprising:
a hole transport region between the first electrode and the organic layer, the hole transport region covering the first electrode; and
an electron transport region between the second electrode and the organic layer, the electron transport region covering the second electrode.

11. The organic light-emitting display apparatus as claimed in claim 10, wherein the hole transport region includes:
a hole injection layer covering the first electrode on the first electrode; and
a hole transport layer covering the first electrode and the hole injection layer on the hole injection layer.

12. The organic light-emitting display apparatus as claimed in claim 10, wherein the electron transport region includes:
an electron injection layer covering the second electrode on the second electrode; and
an electron transport layer covering the second electrode and the electron injection layer on the electron injection layer.

13. The organic light-emitting display apparatus as claimed in claim 1, further comprising an encapsulation layer on the organic layer.

14. The organic light-emitting display apparatus as claimed in claim 13, further comprising an insulation layer between the organic layer and the encapsulation layer.

15. The organic light-emitting display apparatus as claimed in claim 14, wherein a refractive index of the insulation layer is smaller than a refractive index of the organic layer and is equal to a refractive index of the encapsulation layer or greater than the refractive index of the encapsulation layer.

16. The organic light-emitting display apparatus as claimed in claim 15, wherein:
the insulation layer includes a plurality of insulation layers having different refractive indices, and
a refractive index of each of the plurality of insulation layers decreases in a direction toward the encapsulation layer.
